(19) United States
(12) Patent Application Publication
(10) Pub. No.: US 2025/0321250 A1
(43) Pub. Date: Oct. 16, 2025

(54) SMD Components Having Integrated Primary Conductors

(71) Applicant: Vacuumschmelze GmbH & Co. KG, Hanau (DE)

(72) Inventors: Axel Schulze, Hanau (DE); Daniel Jordan, Hanau (DE); Steffen Böttcher, Hanau (DE)

(21) Appl. No.: 19/171,573

(22) Filed: Apr. 7, 2025

(30) Foreign Application Priority Data
Apr. 16, 2024 (DE) 102024110658.1

(51) Int. Cl. G01R 15/18; G01R 15/20; G01R 19/00

(52) U.S. Cl. CPC G01R 15/18; G01R 15/202; G01R 19/0092

(57) ABSTRACT

An electrical component is described. According to one embodiment, the component includes a housing and at least one conductor, the ends of which have contact surfaces for surface mounting. The housing includes structural elements which are configured for holding the conductor on the housing and, at the same time, for allowing a compensation movement of the conductor relative to the housing when the component is placed on a circuit board, such that the contact surfaces at the ends of the conductor are pressed against the circuit board by the weight force of the conductor.

### TECHNICAL FIELD

The present description relates to the field of passive components for surface mounting (surface-mounted devices, SMD).

### BACKGROUND

SMD components are typically soldered onto circuit boards by means of a hot-air oven (by means of what is known as a reflow soldering process). In order to ensure clean and reliable contacting, it is important for the contact surfaces (SMD contact pads) formed on the component are oriented in a coplanar manner and their position is maintained during the soldering process. In practice, sufficient coplanarity is achieved if the contact surfaces of the component deviated from an ideal plane by less than e.g. 100 μm. The actually permitted deviation can depend on the application.

In most cases, SMD components are small and comparatively lightweight parts such as resistors, diodes and capacitors. Since SMD connection technology results in lower costs than PTH (pin through hole) connection technology, there is a certain market pressure to construct ever more components—also larger components such as inductive parts with iron cores, transformers, current sensors and the like—as SMD components. This relates for example to the field of renewable energies and electromobility, and also components which are configured for relatively high currents and powers, for example current sensors with a magnetic core. Such components have, by nature (on account of the high currents), relatively thick conductors, wherein it has been found that connecting wires having large conductor cross-sections are not readily suitable for surface mounting.

For example in the case of current sensors having larger dimensions (e.g. footprint of approximately 30×30 to 100×100 mm² or more) and correspondingly large diameters of the primary conductor (e.g. diameter of 0.5-12 mm or more) the geometric ratios and resulting factors play a significant role. Owing to the larger dimensions and the consequently relatively widely spaced SMD contact surfaces of the component, material stiffness, material warpage and material internal stresses have significantly greater (negative) effects than in the case of small, conventional SMD components. For example, an intrinsic warpage (distortion) of a plastics housing of the component of only a few angular degrees may result, owing to the widely spaced SMD contact surfaces, in a considerable height difference of the contact surfaces in the order of magnitude of millimetres, which is far above the permitted tolerance range. The mentioned requirement of coplanarity is no longer fulfilled in this example.

The inventors have addressed the problem of developing a solution which makes it possible to configure comparatively large components, such as current sensors having integrated primary conductors, in SMD connection technology, in such a way that the SMD contact surfaces are sufficiently coplanar as far as possible irrespective of the actual size of the component and the diameter of the conductor. In particular, this is intended to be achieved without having to resort to highly precise and complex (plastics) geometries.

### SUMMARY

The above-mentioned problem is solved by a component and a current sensor described herein.

According to one embodiment, the component comprises a housing and at least one conductor, the ends of which comprise contact surfaces for surface mounting. The housing comprises structural elements which are configured for holding the conductor on the housing and at the same time for allowing a compensation movement of the conductor relative to the housing when the component is placed on a circuit board, such that the contact surfaces at the ends of the conductor are pressed against the circuit board by the weight force of the conductor.

According to one embodiment, the component is a current sensor. In this case, the conductor, which conducts the load current to be measured, is referred to as the primary conductor. For the purpose of total current measurement or differential current measurement, the current sensor can also comprise two or more primary conductors.

### BRIEF DESCRIPTION OF THE FIGURES

Various embodiments are explained in more detail in the following with reference to drawings. The illustrations are not necessarily true to scale, and the invention is not limited only to the aspects shown. Rather, it is emphasised that the embodiments shown illustrate basic principles.

FIG. 1 shows a horizontally mounted component, for example a current sensor having a magnetic core arranged in a housing and two primary conductors which are guided through the central opening of the magnetic core.

FIG. 2-4 illustrate in more detail structural elements of the housing which hold the primary conductors.

FIG. 5 illustrates the compensation of a tilt (shown exaggerated) of the housing.

FIG. 6-7 show an embodiment of a component (e.g., a current sensor) mounted vertically on a circuit board, wherein the housing of the component comprises slots for guiding through the primary conductors.

FIG. 8-9 show an embodiment in which SMD contact surfaces are formed by an edge metallisation of the sensor board.

### DETAILED DESCRIPTION

The embodiments described here allow for sufficient coplanarity of the SMD connection surfaces for a conventional reflow soldering process even in the case of large components having relatively thick connection wires, in that the thick wires with SMD connection surfaces can be as far as possible mechanically decoupled from the influence of the (housing) geometry of the component and possible manufacturing tolerances. The requirements for the precision of the component geometry (and the associated costs) are not increased thereby.

The embodiments described here are explained on the basis of a current sensor comprising a magnetic core through which a primary conductor is guided. However, this is just one example. The concepts described here can also be applied to other electrical and electronic components (such as current transformers, inductors, etc.) which also do not necessarily have to comprise a magnetic core.

In some embodiments, the housing typical for current sensors and also for other inductive components (with or without a magnetic core) are supplemented by further geometric structures, such as guides, latching elements and slots, with the aim of being able to allow the current-carrying connection wire (in particular the primary conductor), which comprises SMD connection surfaces at the wire ends, to lie on the circuit board, reliably and in a manner suitable for surface mounting, exclusively by its own weight.

In some embodiments, the mentioned geometric structures (e.g. guides and fastening elements) are configured such that a movement of the SMD connection surfaces (e.g. at the ends of the primary conductor) orthogonally to the corresponding connection surface on the circuit board is possible only by the own weight force of the respective conductor, and at the same time the conductor is secured, with the SMD connection surfaces, upon mounting, in such a way that these remain at the desired position upon assembly and during further handling and mounting steps.

Since each primary conductor (e.g. arcuate, substantially U-shaped primary conductor) move orthogonally to the circuit board in a defined space (typically between 0.5-2 mm) and can also be tilted to a small extent (typically up to 5 degrees), there is a rigid relationship between the geometry of the component and the manufacturing tolerances (in particular relating to the housings of the component). Thus, a negative influencing of the primary conductor (and its SMD connection surfaces) owing to tolerance-related height differences and tilting, which would prevent reliable and flat lying of the SMD contact surfaces on the circuit board, is avoided.

Furthermore, an independent movement (i.e. at least in part decoupled from the housing of the component) of the primary conductor allows for compensation of manufacturing tolerances in the circuit board (e.g. on account of bulging and unevenness of the circuit board). That is to say that the component is constructed such that the (primary) conductor(s) are held on the housing of the component (such that falling out is not possible) and at the same time compensation movements of the conductors (relative to the housing) are permitted when placing the component on a circuit board. The contact surfaces at the ends of the conductor are pressed against the circuit board only by the weight force of the conductor. Such a compensation of manufacturing tolerances allows for a reliable soldering process (despite existing manufacturing tolerances). The contact surfaces at the ends of the conductor can be tin-plated.

A further aspect of the embodiments described herein relates to the contacting of the signal connections. These signal connections can typically be configured having significantly smaller cross-sections on account of the lower currents. An approach consists in forming the signal connections directly as SMD connections, wherein orienting the individual signal connections (in part distributed over a large footprint of the component) so as to be permanently coplanar to one another constitutes a certain challenge. Therefore, in some embodiments, a circuit board comprising side or edge metallisation (side plating) is used in order to achieve coplanar signal connections. In this case, the signal connections can be arranged on a separate board (e.g. the sensor board of the current sensor) which allows for contacting of the conventional PTH connections which are then electrically connected to corresponding metallisations at the edge of the circuit board. The mentioned side/edge metallisation forms the actual SMD connection surfaces, which, together with the respective component (including the primary conductor), can be soldered securely to a circuit board in a reflow process.

In some embodiments, the mentioned side/edge metallisation, which forms the connection surfaces of the signal connections, can also be arranged directly on the board (sensor board) which also carries other electronic circuits—in the case of current sensors e.g. the entire sensor electronics. In this case, no separate board is required for the signal connections. The sensor board can be mounted in or on the housing of the component.

The embodiments described in the following relate specifically to a current sensor (e.g. an open-loop or a closed-loop current sensor). Of course, the concepts described here can also be applied to other types of component, in particular inductive components with and without a magnetic core. The magnetic core may be an annular core with or without an air gap.

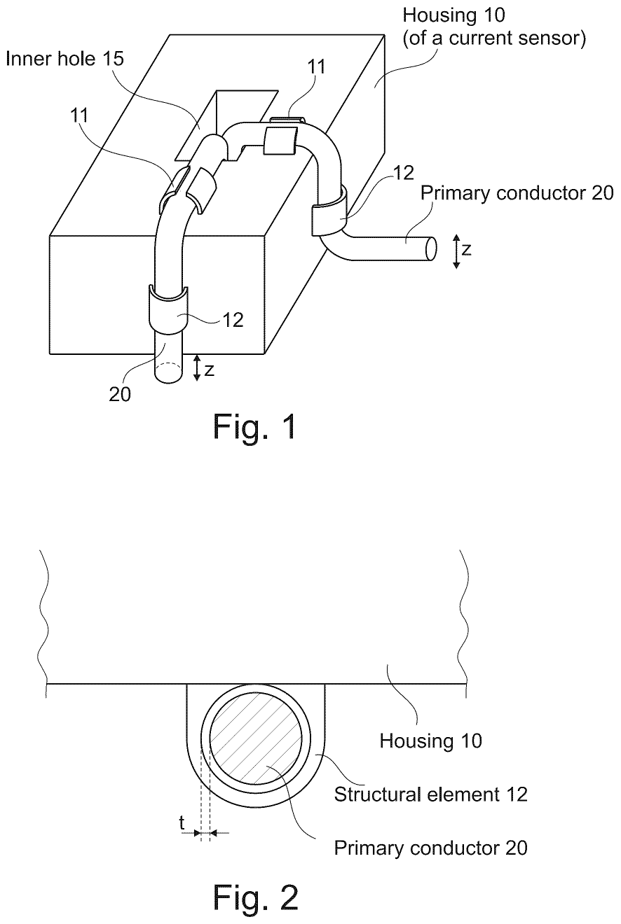

FIG. 1 shows a current sensor in a horizontal configuration, i.e. the inner hole 15 of the magnetically soft core (in the housing 10) extends substantially orthogonally to the surface of the circuit board on which the current sensor is intended to be mounted. In contrast thereto, in the case of a current sensor in a vertical configuration, the inner hole (i.e. its longitudinal axis) extends in parallel with the surface of the circuit board. In both cases, the primary conductors are curved in a substantially U-shaped manner and are guided through the central opening of the sensor housing, while the two legs of the U-shape contact the circuit board.

In the example shown in FIG. 1 (horizontal current sensor), the primary conductors 20 (current loop) are prefabricated wire pieces which are curved in a U-shape and which can be threaded into the central opening of the current sensor housing 10. The housing 10 can be made of plastics material and comprises various structural elements 11 and 12 which are configured for holding the primary conductors 20 loosely on the housing 10 while at the same time (i.e., concurrently)—within certain limits—a movement of the primary conductor 20 normally to the circuit board (in the z-direction in FIG. 1) is made possible. A slight tilting of the primary conductor 20 in a plane normal to the circuit board is also made possible. That is to say that the structural elements 11 and 12 prevent the primary conductor 20 from falling out when the current sensor is handled during the assembly and the mounting on the circuit board, but allow for a movement of the primary conductor 20 relative to the housing 10, within specifiable limits.

According to the example from FIG. 1, the ends (e.g. the round end face) of the conductor 20 serve as an SMD connection surface. The primary conductor 20 is guided through one or more structural elements 12 configured as guide sleeves, wherein play is present between the primary conductor 20 and the inside wall of the guide sleeve (i.e. a spacing t between the guide sleeve and the primary conductor). The play allows for a displacement of the primary conductor in the z-direction (since the primary conductor is not clamped in the guide sleeve), and it furthermore allows for slight tilting of the primary conductor and consequently compensation of angular errors owing to manufacturing-based tolerances.

In the example shown in FIG. 2, the conductor 20 as well as the guide sleeve 12 has a circular contour, wherein the (inside) diameter of the guide sleeve 12 is 2 t greater than the (outside) diameter of the primary conductor 20. The play t can be a few tenths of a millimetre. The guide sleeves can also comprise a slot which is dimensioned such that the conductor can tilt only in one plane (e.g. xz-plane).

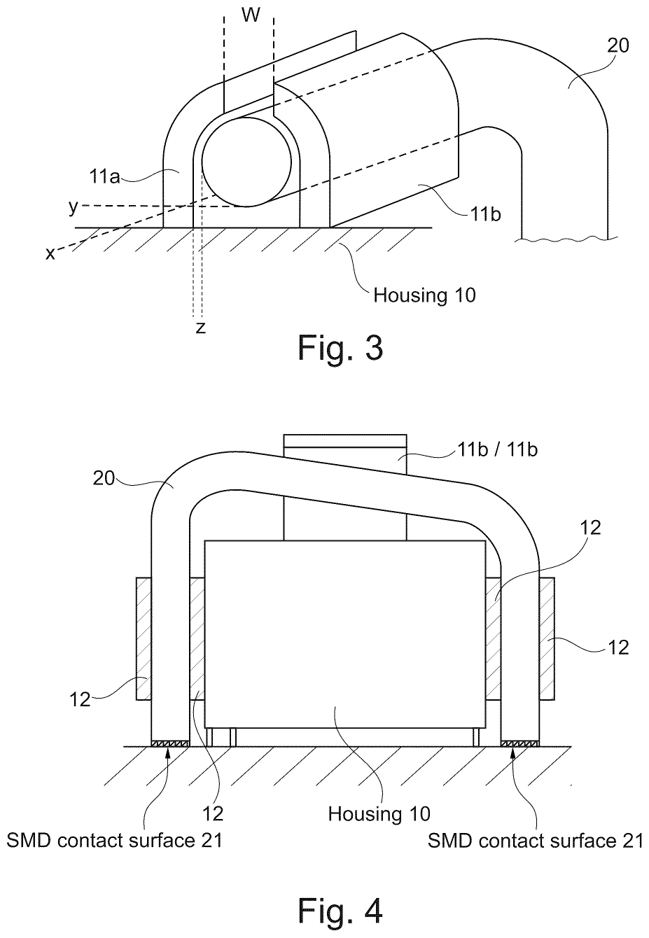

In addition to a slight tilting movement, the structural element 12 substantially allows for a movement of the primary conductor 20 in the vertical (i.e. in the z-) direction. In order that the primary conductor cannot fall out of the guide sleeve 12 in the case of handling of the component, according to one embodiment the freedom of movement of the primary conductor in the z-direction is limited by a further structural element 11. An example for this is shown in FIG. 3.

According to FIG. 3, the structural element 11 is a guide sleeve having a slit of width w in the longitudinal direction of the sleeve, such that two resilient latching elements 11a and 11b are formed, which allow for a type of snap-in connection. The primary conductor can be pressed through the slit into the guide sleeve 11 (i.e. between the latching elements 11a and 11b), wherein during this latching process the latching elements 11a and 11b are pressed apart from one another and then spring back. Since the diameter d of the primary conductor is greater than the width w of the slit (w<d), the primary conductor 20 is held in a form-fitting manner in the structural element/the guide sleeve, without the conductor being clamped. The conductor 20 and the latching elements 11a and 11b form a snap-in connection.

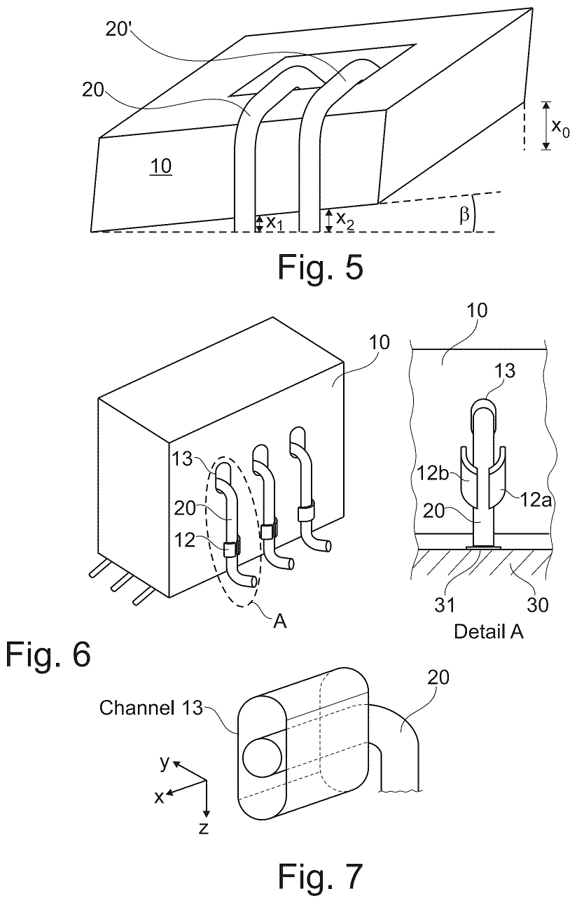

The structure shown in FIG. 1-4 allows for a restricted but defined movement in a vertical direction (z) and at the same time a tilted position (angle α in the xz-plane) of the conductor 20 within the latching elements 11a, 11b. This situation is shown in cross-section in FIG. 4. Thus, possible height differences of the two SMD connections (see FIG. 4, SMD contact surfaces 21) at the ends of the conductor 20 curved to a U-shaped arc and a tilted position of the entire current sensor (spacings x₁≠x₂, angle β), as shown in FIG. 5, can be compensated. Furthermore, unevenness or bulging of the circuit board can be compensated. Of course, the tilted position of the housing 10 is shown exaggerated in FIG. 5. The different spacings x₁ and x₂ can be compensated by the conductor 20, since this can perform a compensation movement in the structural elements 11, 12.

It can also be seen in FIGS. 3 and 4 that the structural elements 11 and 12 on the housing (in the example shown, the latching elements 11a, 11b on the top and the structural elements 12 on the side of the housing 10) are configured such that the conductor 20 is on the one hand guided through, and on the other hand a movement of the conductor 20 in at least one direction (y-direction) is blocked. As a result, the conductor 20 curved to an arc can move freely in one plane (xz-plane) within defined limits.

In this case, the specific design of the SMD connections (i.e. the SMD contact surfaces) at the ends of the primary conductor 20 (in the example in FIG. 5 a variant having a plurality of conductors 20 and 20′ is shown) can take place in various manners. One possibility consists, for example, in using the (e.g. circular or rectangular) end faces of the wire 20 directly as SMD contact surfaces. This variant is shown in FIG. 4. A further possibility consists in angling the ends of the conductor 20 by 90° (cf. FIG. 6) and consequently using the lateral surface of the previously angled region as the SMD contact surface. Furthermore, it is also possible to produce an SMD-compatible connection (not shown in the drawings) by means of separate SMD contact feet that are connected to the conductor ends.

FIGS. 6 and 7 show an example of a current sensor in a vertical configuration. In this case, the primary conductors 20 can be guided through openings 13 which extend through the housing 10. The openings 13 have an elongate cross-section (slot) which allows for a movement/tilted position of the wires 20 within the opening. The structural elements 12a and 12b arranged laterally on the housing 10 form, together with the conductor 20, a snap-in connection as described above with reference to FIG. 3 (cf. latching elements 11a and 11b in FIG. 3). During assembly, the primary conductor 20 is first guided through the associated horizontal opening 13 and subsequently angled downwards (towards the circuit board) by 90° and in the process pushed through the gap between the latching elements 12a and 12b until the conductor 20 latches in.

The shape of the openings 13 is shown in more detail in FIG. 7. This elongate shape of the cross-section of the openings 13 allows for a vertical movement (in the z-direction) and tilting (rotation about the y-axis in the xz-plane) of the conductor 20 within the opening 13, but at the same time ensures tight guidance in the y-direction and thus prevents a lateral tilted position of the entire conductor 20 curved to an arc. The diagram in FIG. 6 denoted “Detail A” also shows the SMD connection of a conductor 20 of the current sensor to a circuit board 30. The solder pad on the circuit board 30 belonging to one end of the conductor 20 is denoted by 31.

In the embodiments shown here, the primary conductor 20 is not firmly surrounded or fixed either in the opening 13 or in the laterally arranged guides formed by the latching elements 12a and 12b (i.e. the conductors are loose). Therefore, the conductors 20 (and consequently the SMD contact surfaces at their ends) can sit on the associated SMD solder pads of the circuit board only by their own weight. In this case, the ranges of movement defined within the structural elements (latching elements 11a-b, 12a-b, opening 13, etc.) provide the possibility of compensating any length and angular differences as well as tolerances of the curved primary conductors 20, unevennesses of the circuit board, and tolerances in the configuration of the current sensor body, and thus of mechanically decoupling the conductor(s) from the housing 10 (within defined limits).

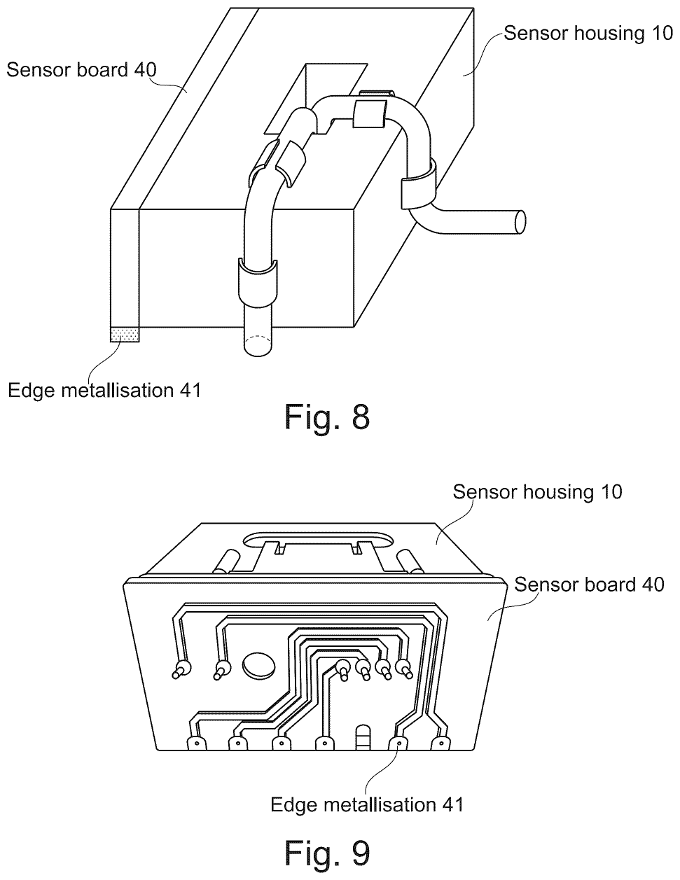

FIG. 8-9 show an embodiment in which SMD contact surfaces are formed by an edge metallisation of the sensor board. This technique for producing SMD connections relates in particular to the signal connections of the current sensor, whereas the primary conductor carries the load current. These, as well as the primary conductors 20, can be distributed over a large footprint of the component and must also be coplanar. Therefore, in the embodiment shown, a sensor board 40 (which can also accommodate the sensor electronics) having a structured side or edge metallisation 41 (side plating) is used. The side/edge metallisation forms the actual SMD connection surfaces, which, together with the respective component (including the primary conductor 20), can be soldered securely to a circuit board in a reflow process. In other words, the sensor board 40 in an adapter board which comprises SMD connection surfaces and can accommodate a plurality of electronic components (also with PTH connections).

The features of the embodiments discussed here in relation to the figures can also be combined to form further embodiments. Furthermore, concepts as described here can be applied to various types of electrical and electronic components, irrespective of the actual function of the components. As already mentioned, the embodiments do not necessarily have to comprise a magnetic core having a (secondary) winding. In particular open-loop current sensors can also be constructed without a secondary winding and also without a magnetic core.

If no secondary winding is used as a magnetic field-sensitive element in the current sensor, e.g. a Hall sensor can be used as the magnetic field-sensitive element for current measurement.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of”' should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A component, comprising:
a housing; and
a conductor having a first end and a second end,
wherein both the first end and the second end of the conductor comprise a contact surface configured for surface mounting,
wherein the housing comprises a plurality of structural elements configured to hold the conductor on the housing and concurrently allow a compensation movement of the conductor relative to the housing when the component is placed on a circuit board, such that the contact surface of the first end and the contact surface of the second end of the conductor are pressed against the circuit board by a weight force of the conductor.

2. The component of claim 1, wherein the structural elements of the housing are configured to guide the conductor through the structural elements and block a movement of the conductor in at least one direction.

3. The component of claim 1, wherein the structural elements of the housing are configured to guide the conductor through the structural elements such that a movement of the conductor in a plane positioned normally on the circuit board is enabled.

4. The component of claim 1, wherein the structural elements of the housing are configured to enable a tilting movement of the conductor about at most 5 degrees with respect to a target position, and wherein the target position is specified by the structural elements of the housing.

5. The component of claim 1, wherein the conductor is curved in a substantially U-shaped manner.

6. The component of claim 1, wherein the contact surface of the first end of the conductor is formed by an end face of the first end, and wherein the contact surface of the second end of the conductor is formed by an end face of the second end.

7. The component of claim 1, wherein the first end of the conductor is curved and the contact surface of the first end is formed by a side face of the first end, and wherein the second end of the conductor is curved and the contact surface of the second end is formed by a side face of the second end.

8. The component of claim 1, wherein the contact surface of the first end of the conductor is formed by a first contact foot mounted on the first end, and wherein the contact surface of the second end of the conductor is formed by a second contact foot mounted on the second end.

9. The component of claim 1, further comprising:
a board having a structured edge metallisation arranged in or on the housing and connected to the housing, such that the edge metallisation forms one or more contact surfaces configured for the surface mounting.

10. The component of claim 1, further comprising:
a magnetically soft core arranged in the housing.

11. The component of claim 1, further comprising:
an annular core arranged in the housing,
wherein the conductor is guided through an opening in the annular core.

12. The component of claim 1, wherein the conductor is guided through an opening in the housing.

13. The component of claim 1, wherein the structural elements of the housing comprise at least one pair of latching elements configured to latch the conductor and prevent the conductor from falling out.

14. The component of claim 1, wherein the structural elements of the housing comprise at least one or more slots.

15. A current sensor device, comprising:
a sensor housing; and
a substantially U-shaped primary conductor guided through the sensor housing and having a first end and a second end,
wherein both the first end and the second end of the primary conductor comprise a contact surface configured for surface mounting,
wherein the sensor housing comprises a plurality of structural elements configured to hold the primary conductor on the housing and concurrently allow a compensation movement of the primary conductor relative to the housing when the current sensor device is placed on a circuit board, such that the contact surface of the first end and the contact surface of the second end of the primary conductor are pressed against the circuit board by a weight force of the primary conductor.

16. The current sensor device of claim 15, wherein the sensor housing comprises a magnetically soft core.

17. A method for surface mounting of a component having a housing and a conductor with a first end and a second end, both the first end and the second end of the conductor having a contact surface configured for surface mounting, the housing having a plurality of structural elements configured to hold the conductor on the housing and concurrently allow a compensation movement of the conductor relative to the housing when the component is placed on a circuit board, such that the contact surface of the first end and the contact surface of the second end of the conductor are pressed against the circuit board by a weight force of the conductor, the method comprising:
positioning the component on the circuit board such that the contact surface of the first end of the conductor touches a first solder pad on the circuit board and the contact surface of the second end of the conductor touches a second solder pad on the circuit board, wherein the compensation movement occurs when the component is placed on the circuit board; and
carrying out a soldering process to connect the contact surface of the first end of the conductor to the first solder pad on the circuit board and to connect the contact surface of the second end of the conductor to the second solder pad on the circuit board.
